(19) United States
(12) Patent Application Publication
(10) Pub. No.: US 2008/0135901 A1
(43) Pub. Date: Jun. 12, 2008

(54) SEMICONDUCTOR MEMORY AND METHOD OF MANUFACTURING THE SAME

(76) Inventors: Yoshiro SHIMOJO, Kanagawa-ken (JP); Susumu Shuto, Kanagawa-ken (JP); Iwao Kunishima, Kanagawa-ken (JP); Tohru Ozaki, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/939,955

(22) Filed: Nov. 14, 2007

(30) Foreign Application Priority Data
Nov. 16, 2006 (JP) 2006-310636

(51) Int. Cl. H01L 29/76; H01L 21/8246

(52) U.S. Cl. 257/295; 438/239; 438/3; 257/E21.664; 257/E29.226

(57) ABSTRACT

A semiconductor memory, comprising: a first memory cell transistor disposed on a semiconductor substrate; a second memory cell transistor disposed on the semiconductor substrate and having a first source-drain region in common with the first memory cell transistor; a first ferroelectric capacitor disposed with a via in between above a second source-drain region of the first memory cell transistor; a second ferroelectric capacitor disposed with a via in between above a second source-drain region of the second memory cell transistor; an interlayer dielectric disposed on the semiconductor substrate, as coating the memory cell transistors and the ferroelectric capacitors, the interlayer dielectric having a contact hole through which the first source-drain region is partially exposed at the bottom and upper electrodes of the first and second ferroelectric capacitors are partially exposed at the top; and a wiring layer filled into the contact hole, which connects the first source-drain region, the upper electrode of the first ferroelectric capacitor, and the second ferroelectric capacitor.

### CROSS-REFERENCE TO RELATED APPLICATION

This application is based upon and claims the benefit of priority from the prior Japanese Patent Application No. 2006-310636, filed on Nov. 16, 2006, the entire contents of which are incorporated herein by reference.

### BACKGROUND OF THE INVENTION

1. Field of the Invention

The present invention relates to a ferroelectric memory device.

2. Description of the Prior Art

Under development is next-generation nonvolatile memory intended to achieve capacity, speed and cost comparable to those of DRAM (dynamic random access memory), having the features of being capable of higher rewrite speed than that of conventional EEPROM (electrically erasable programmable read-only memory) and flash memory and also permitting the number of rewrite operations five or more orders of magnitude larger than what is possible with the conventional memory. The types of next-generation nonvolatile memory include FeRAM (ferroelectric random access memory), MRAM (magnetic random access memory), PRAM (phase change random access memory), and RRAM (resistive random access memory). The FeRAM, ferroelectric memory, includes a memory cell formed of a ferroelectric capacitor and a transistor. See U.S. Pat. No. 6,521,929, for example.

For chain FeRAM disclosed in U.S. Pat. No. 6,521,929, and so on, a cell-by-cell connection between an upper electrode of the ferroelectric capacitor and a memory cell transistor involves two separate processes for contact hole formation in the memory cell transistor because of a contact plug having a large aspect ratio. This leads to the problem of complicating the manufacturing process for the chain FeRAM to act as the ferroelectric memory and hence increasing the number of process steps. Moreover, a finer memory transistor leads to the problem of making it impossible to achieve high-density ferroelectric memory because of difficulty in doing the two separate processes for the contact hole formation in the memory cell transistor by reason of a problem involved in mask alignment accuracy, and so on.

### SUMMARY OF THE INVENTION

According to an aspect of the present invention, there is provided a semiconductor memory, comprising:

a first memory cell transistor disposed on a semiconductor substrate;

a second memory cell transistor disposed on the semiconductor substrate and having a first source-drain region in common with the first memory cell transistor;

a first ferroelectric capacitor disposed with a via in between above a second source-drain region of the first memory cell transistor;

a second ferroelectric capacitor disposed with a via in between above a second source-drain region of the second memory cell transistor;

an interlayer dielectric disposed on the semiconductor substrate, as coating the memory cell transistors and the ferroelectric capacitors, the interlayer dielectric having a contact hole through which the first source-drain region is partially exposed at the bottom and upper electrodes of the first and second ferroelectric capacitors are partially exposed at the top; and

a wiring layer filled into the contact hole, which connects the first source-drain region, the upper electrode of the first ferroelectric capacitor, and the second ferroelectric capacitor.

According to another aspect of the present invention, there is provided a semiconductor memory, comprising:

a first memory cell transistor disposed on a semiconductor substrate;

a second memory cell transistor disposed on the semiconductor substrate and having a first source-drain region in common with the first memory cell transistor;

a first ferroelectric capacitor formed of a capacitor lower electrode, a ferroelectric film and a capacitor upper electrode, disposed with a via in between above a second source-drain region of the first memory cell transistor;

a second ferroelectric capacitor formed of the capacitor lower electrode, the ferroelectric film and the capacitor upper electrode, disposed with a via in between above a second source-drain region of the second memory cell transistor;

a sidewall film disposed on each of the sides of the first and second ferroelectric capacitors;

an interlayer dielectric disposed on the semiconductor substrate, as coating the memory cell transistors, the ferroelectric capacitors and the sidewall films, the interlayer dielectric having a contact hole through which the first source-drain region is partially exposed at the bottom and the upper edges of the upper electrodes of the first and second ferroelectric capacitors and the sides of the sidewall films are exposed at the top; and

a wiring layer filled into the contact hole, which connects the first source-drain region, the upper electrode of the first ferroelectric capacitor, and the second ferroelectric capacitor.

According to another aspect of the present invention, there is provided a semiconductor memory, comprising:

a first memory cell transistor disposed on a semiconductor substrate;

a second memory cell transistor disposed on the semiconductor substrate and having a first source-drain region in common with the first memory cell transistor;

a first ferroelectric capacitor formed of a capacitor lower electrode, a ferroelectric film and a capacitor upper electrode, disposed with a via in between above a second source-drain region of the first memory cell transistor;

a second ferroelectric capacitor formed of the capacitor lower electrode, the ferroelectric film and the capacitor upper electrode, disposed with a via in between above a second source-drain region of the second memory cell transistor;

a sidewall film disposed on each of the sides of the first and second ferroelectric capacitors; and

a wiring layer disposed, in contact with the sides of the sidewall films, on the first source-drain region of the first and second memory cell transistors, which connects the via, the capacitor upper electrode of the first ferroelectric capacitor, and the capacitor upper electrode of the second ferroelectric capacitor.

According to another aspect of the present invention, there is provided a method of manufacturing a semiconductor memory, comprising:

forming a contact opening-in a first interlayer dielectric formed on a source-drain region of a memory cell transistor, and selectively forming sidewall films on the sides of first and second ferroelectric capacitors each formed above the source-drain region of the memory cell transistor with a via filled into the contact opening in between;

forming a first contact by exposing the first ferroelectric capacitor, the second ferroelectric capacitor and the sidewall films by etching a second interlayer dielectric formed on the sidewall films, the first ferroelectric capacitor and the second ferroelectric capacitor by use of RIE method with a resist film acting as a mask;

forming a second contact by exposing the source-drain region of the memory cell transistor by etching the first interlayer dielectric by use of the RIE method with the sidewall films acting as a mask; and

filling a wiring layer into the first and second contacts.

According to another aspect of the present invention, there is provided a method of manufacturing a semiconductor memory, comprising:

forming a contact opening in a first interlayer dielectric formed on a source-drain region of a memory cell transistor, and forming first and second ferroelectric capacitors above the source-drain region of the memory cell transistor with a via filled into the contact opening in between;

forming a first contact by etching a second interlayer dielectric formed on the first and second ferroelectric capacitors by use of RIE method with a first resist film acting as a mask until the first and second ferroelectric capacitors are partially exposed;

forming a second contact having a narrower width than that of the first contact, by exposing the source-drain region of the memory cell transistor by etching the first and second interlayer dielectrics by use of the RIE method with a second resist film acting as a mask, the second resist film having an opening formed between the first and second ferroelectric capacitors; and

filling a wiring layer into the first and second contacts.

According to another aspect of the present invention, there is provided a method of manufacturing a semiconductor memory, comprising:

forming a contact opening in a first interlayer dielectric formed on a source-drain region of a memory cell transistor, and forming first and second ferroelectric capacitors above the source-drain region of the memory cell transistor with a via filled into the contact opening in between;

forming a first contact by etching a second interlayer dielectric formed on the first and second ferroelectric capacitors by use of isotropic dry etching method with a resist film acting as a mask until the first and second ferroelectric capacitors are partially exposed;

forming a second contact having a narrower width than that of the first contact, by exposing the source-drain region of the memory cell transistor by etching the first and second interlayer dielectrics by use of RIE method with the resist film acting as a mask; and

filling a wiring layer into the first and second contacts.

### BRIEF DESCRIPTION OF THE DRAWINGS

FIG. 1 is a plan view showing a memory cell unit of ferroelectric memory according to a first embodiment of the present invention.

FIG. 2 is a cross-sectional view taken along the line A-A of FIG. 1, showing the memory cell unit of the ferroelectric memory.

FIG. 3 is a cross-sectional view showing a manufacturing process for the ferroelectric memory according to the first embodiment of the present invention.

FIG. 4 is a cross-sectional view showing the manufacturing process for the ferroelectric memory according to the first embodiment of the present invention.

FIG. 5 is a cross-sectional view showing the manufacturing process for the ferroelectric memory according to the first embodiment of the present invention.

FIG. 6 is a cross-sectional view showing a memory cell unit of ferroelectric memory according to a second embodiment of the present invention.

FIG. 7 is a cross-sectional view showing a manufacturing process for the ferroelectric memory according to the second embodiment of the present invention.

FIG. 8 is a cross-sectional view showing the manufacturing process for the ferroelectric memory according to the second embodiment of the present invention.

FIG. 9 is a plan view showing a memory cell unit of ferroelectric memory according to a third embodiment of the present invention.

FIG. 10 is a cross-sectional view taken along the line B-B of FIG. 9, showing the memory cell unit of the ferroelectric memory.

FIG. 11 is a cross-sectional view taken along the line C-C of FIG. 9, showing the memory cell unit of the ferroelectric memory.

FIG. 12 is a cross-sectional view showing a manufacturing process for the ferroelectric memory according to the third embodiment of the present invention.

FIG. 13 is a cross-sectional view showing the manufacturing process for the ferroelectric memory according to the third embodiment of the present invention.

FIG. 14 is a cross-sectional view showing the manufacturing process for the ferroelectric memory according to the third embodiment of the present invention.

FIG. 15 is a cross-sectional view showing a memory cell unit of ferroelectric memory according to a fourth embodiment of the present invention.

### DESCRIPTION OF THE PREFERRED EMBODIMENTS

Description will be given below with reference to the drawings with regard to embodiments of the present invention.

### First embodiment

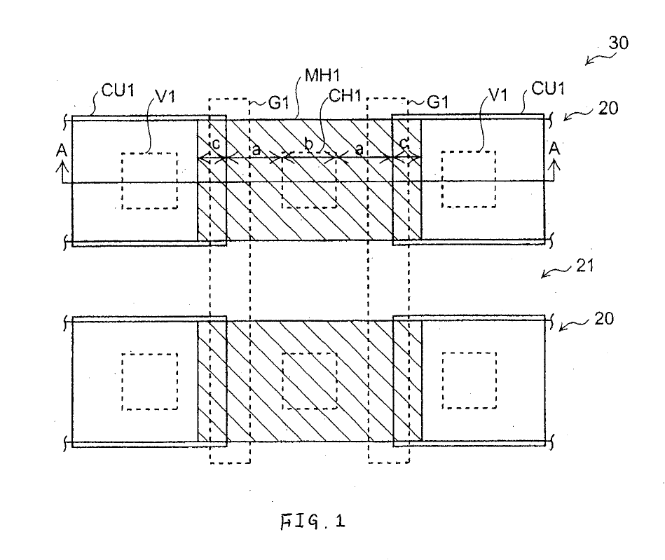

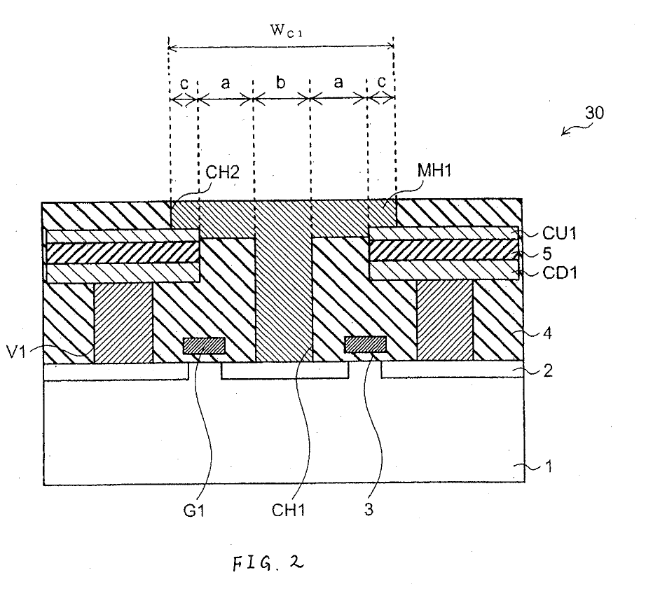

Firstly, description will be given with reference to the drawings with regard to a semiconductor memory and a method of manufacturing the same according to a first embodiment of the present invention. FIG. 1 is a plan view showing a memory cell unit of ferroelectric memory, and FIG. 2 is a cross-sectional view taken along the line A-A of FIG. 1, showing the memory cell unit of the ferroelectric memory. In the first embodiment, chain FeRAM (ferroelectric random access memory) to act as the ferroelectric memory is employed and is constructed to have a simplified connection between a ferroelectric film capacitor and a memory cell transistor.

As shown in FIG. 1, ferroelectric memory (or chain FeRAM) 30 is provided with plural memory cell transistor units 20 and STI (shallow trench isolation) 21 that acts as a device isolation region. The ferroelectric memory (or chain FeRAM) 30 includes a cell-by-cell connection between an upper electrode of the ferroelectric film capacitor and the memory cell transistor.

The memory cell transistor unit 20 includes plural memory cell transistors formed as arranged from side to side of FIG. 1, and is provided with a gate electrode G1, a contact hole CH1, a via (or plug electrode) V1, a capacitor upper electrode CU1, and a wiring layer MH1. The memory cell transistor unit 20 is isolated on its periphery by the STI 21.

The plural gate electrodes G1 are formed in a parallel arrangement, as being spaced at predetermined intervals across the plural memory cell transistor units 20 from top to bottom of FIG. 1. The contact hole CH1 is formed as disposed between the gate electrodes G1 and G1 and also within the memory cell transistor unit 20. The via (or plug electrode) V1 is formed as disposed immediately underneath the ferroelectric capacitor, The wiring layer MH1 is formed as extending over the contact hole CH1 and to the capacitor upper electrode CU1.

At this point, the width of the contact hole CH1 is of a dimension “b,” and the gap between the contact hole CH1 and the capacitor upper electrode CU1 is of a dimension “a.” The capacitor upper electrode CU1 and the wiring layer MH1 are formed as overlapping by a dimension “c,” and they are in contact with each other in an area of the dimension “c.”

As shown in FIG. 2, the ferroelectric memory (or chain FeRAM) 30 includes a source-drain region 2 selectively disposed on top of a semiconductor substrate 1, and the source-drain region 2 is of an opposite conduction type to that of the semiconductor substrate 1 of the memory cell transistor. The gate electrode G1 is selectively disposed above a region between the source-drain regions 2 with a gate insulating film 3 in between. An insulating film 4 to act as an interlayer dielectric is disposed as coating the source-drain region 2 and the gate electrode G1.

The vias (or plug electrodes) V1 are disposed so that the right and left source-drain regions 2 are partially exposed therethrough. The ferroelectric capacitor, which is formed of a capacitor lower electrode CD1, a ferroelectric film 5 and the capacitor upper electrode CU1 and is larger than the via (or plug electrode) V1, is formed as stacked on top of the via (or plug electrode) V1.

The contact hole CH1 is disposed in the insulating film 4 formed between the two gate electrodes G1 so that the central source-drain region 2 is exposed therethrough. A contact hole CH2, which the capacitor upper electrode CU1 is partially exposed through and which has a greater width W_{c1} than that of the contact hole CH1, is disposed above the contact hole CH1. A contact hole formed of the contact hole CH1 and the contact hole CH2 has a T shape. The contact hole area above the exposed central source-drain region 2 is filled with the wiring layer MH1 with the same height as that of the insulating film 4. Herein, the contact hole CH1 is also called a “via contact (or first via contact),” and the contact hole CH2 is also called a “via contact (or second via contact).”

The wiring layer MH1 serves to electrically connect a first ferroelectric capacitor (shown in the left-hand part of FIG. 2) disposed with the via (or plug electrode) V1 in between above the source-drain region 2 (shown in the left-hand part of FIG. 2) to act as a first source-drain region of the memory cell transistor (or first memory cell transistor) shown in the left-hand part of FIG. 2, a second ferroelectric capacitor (shown in the right-hand part of FIG. 2) disposed with the via (or plug electrode) V1 in between above the source-drain region 2 (shown in the right-hand part of FIG. 2) to act as a second source-drain region of the memory cell transistor (or second memory cell transistor) shown in the right-hand part of FIG. 2, and the source-drain region 2 (shown in the center of FIG. 2) to act as a third source-drain region of the memory cell transistor (or first memory cell transistor) and the memory cell transistor (or second memory cell transistor). In other words, the wiring layer MH1 has the function of acting as a wiring to provide an electrical connection between the source-drain region 2 and the ferroelectric capacitor and the function of acting as the via (or via electrode) of the source-drain region 2.

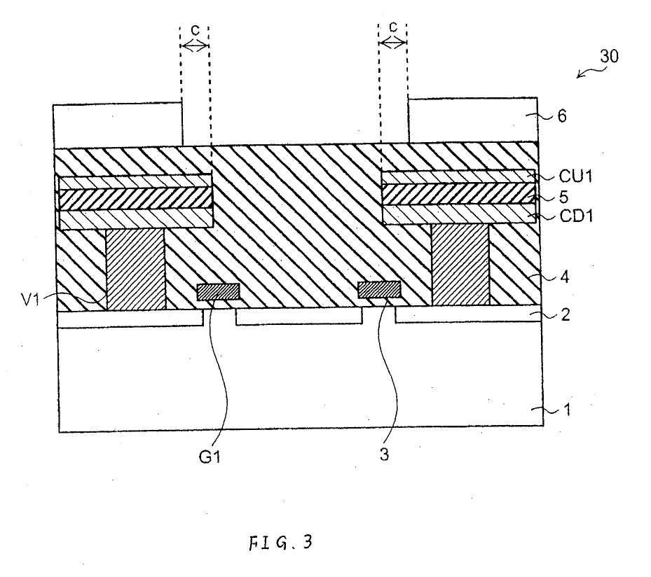

Description will now be given with reference to FIGS. 3 to 5 with regard to a method of manufacturing the ferroelectric memory. FIGS. 3 to 5 are cross-sectional views showing steps in a manufacturing process for the ferroelectric memory.

As shown in FIG. 3, first, the STI 21 to provide isolation between the memory cell transistor units 20 is formed on the semiconductor substrate 1, and the memory cell transistor formed of the gate insulating film 3, the gate electrode G1, the source-drain region 2, and so on is formed on the memory cell transistor unit 20.

Then, the insulating film 4 is deposited on the semiconductor substrate 1, a plug contact is formed above the source-drain region 2, and the via (or plug electrode) V1 is deposited. Although W (tungsten) is herein used for the via (or plug electrode) V1, a polycrystalline silicon film having high impurity concentration, or the like may be used.

Then, the capacitor lower electrode CD1, the ferroelectric film 5 and the capacitor upper electrode CU1 are deposited in sequence in contact with the via (or plug electrode) V1. Although Pt (platinum) is herein used for the capacitor lower electrode CD1, Ir (iridium), IrO₂ (iridium oxide) or the like may be used. Although PZT (lead zirconate titanate, PbZrTiO₃) is used for the ferroelectric film 5, SBT (strontium bismuth tantalate, SrBi₂Ta₂O₉), BLT (lanthanum-doped bismuth titanate, (Bi, La)₄Ti3O₁₂) or the like may be used. Although Pt (platinum) is used for the capacitor upper electrode CU1, Ir (iridium), IrO₂ (iridium oxide) or the like may be used.

Then, a resist film is formed by use of well-known lithography technique, and the capacitor lower electrode CD1, the ferroelectric film 5 and the capacitor upper electrode CU1, except for a ferroelectric capacitor region, are etched away by use of, for example, RIE (reactive ion etching) method with the resist film acting as a mask. The resist film is removed, and thereafter the insulating film 4 is redeposited.

Then, a resist film 6 for use in the formation of the upper contact hole CH2 is formed by use of well-known lithography technique. At this point, the resist film 6 is formed as remaining by the dimension “c” inwardly of the ferroelectric capacitor region from an edge of the ferroelectric capacitor region.

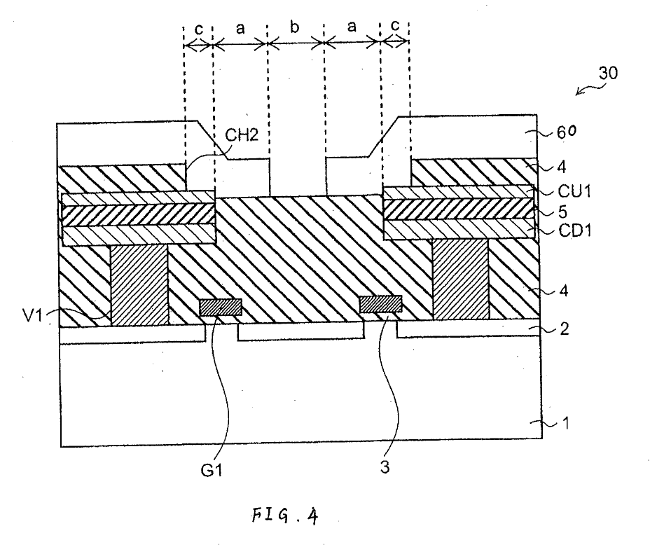

As shown in FIG. 4, then, the insulating film 4 is perpendicularly etched partway through the ferroelectric capacitor region by use of, for example, RIE method with the resist film 6 acting as a mask. At this point, with the RIE method, the capacitor upper electrode CU1 undergoes little etching because the etching rate of the insulating film 4 is very great relative to that of the capacitor upper electrode CU1 (that is, the selective etching ratio of the etching rate of the insulating film 4 to the etching rate of the capacitor upper electrode CU1 is large).

Then, the resist film 6 is removed, and thereafter the resist film 60 for use in the formation of the lower contact hole CH1 is formed by use of well-known lithography technique. At this point, the resist film 60 is formed in such a manner that the width of an opening therein is of the dimension “b” and the gap between an edge of the opening and the ferroelectric capacitor region is of the dimension “a.”

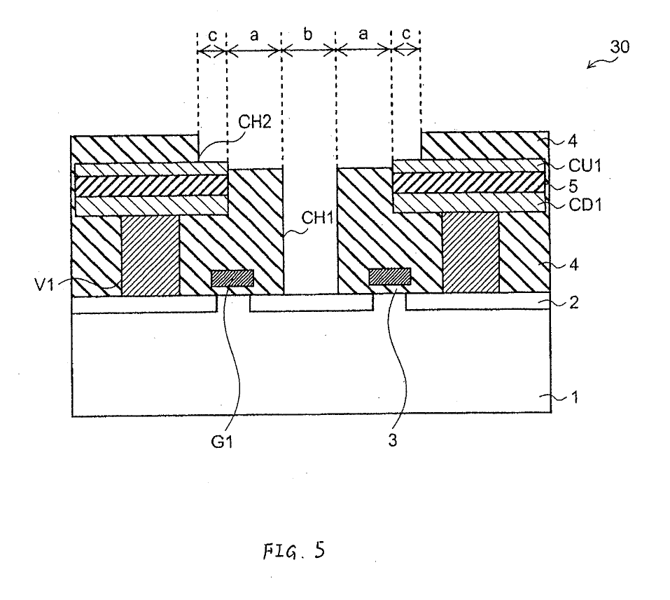

As shown in FIG. 5, then, the lower contact hole CH1 is formed by perpendicularly etching the insulating film 4 to the source-drain region 2 by use of, for example, RIE method with the resist film 60 acting as a mask. Then, the resist film 60 is removed, and thereafter the wiring layer MH1 is deposited in the contact hole CH1 and the contact hole CH2 by use of, for example, well-known the damascene method. Herein, the method is also called “dual damascene method” since the via contact and the wiring are simultaneously formed.

To form the wiring layer MH1, specifically, a barrier metal (for example, TiN (titanium nitride)) is first formed by use of PVD (physical vapor deposition) method or CVD (chemical vapor deposition) method. Then, Cu (copper) is deposited as a wiring metal in the contact hole CH1 and the contact hole CH2 by use of, for example, CVD method. Then, the Cu layer and the barrier metal on the insulating film 4, except for the contact hole CH2, are polished away by use of, for example, CMP (chemical mechanical polishing) method. Incidentally, W (tungsten) may be used in place of Cu. Electroplating method or the like may be used in place of the CVD method to form the wiring metal.

At this point, desirably, the film thickness of the insulating film 4 on the capacitor upper electrode CU1 is set allowing for the thickness of the wiring layer MH1 formed by means of the damascene method (or the thickness of the wiring layer MH1 in the contact hole CH1) and the amount of the wiring layer MH1 removed by means of the CMP method.

After the formation of the wiring layer MH1, the formation of an interlayer dielectric and a wiring layer and so on take place using well-known technique, thereby yielding the completion of the ferroelectric memory 30 to act as the chain FeRAM.

According to the semiconductor memory and the method of manufacturing the same according to the first embodiment of the present invention, as described above, the vias (or plug electrodes) V1 are disposed so that the right and left source-drain regions 2 of the memory cell transistors are partially exposed therethrough. The ferroelectric capacitor formed of the capacitor lower electrode CD1, the ferroelectric film 5, and the capacitor upper electrode CU1 is formed as stacked on top of the via (or plug electrode) V1. The contact hole CH1 is disposed in the insulating film 4 formed between the two gate electrodes G1 so that the central source-drain region 2 is exposed therethrough. The contact hole CH2, which the capacitor upper electrode CU1 is partially exposed through and which is larger than the contact hole CH1, is disposed above the contact hole CH1. The contact area above the exposed central source-drain region 2 is filled with the wiring layer MH1 with the same height as that of the insulating film 4. The wiring layer MH1 has the function of acting as the wiring to provide the electrical connection between the source-drain region 2 and the ferroelectric capacitor and the function of acting as the via (or via electrode) of the source-drain region 2.

Thereby, the manufacturing process can become simpler than hitherto. Since the contact area filled with the wiring layer MH1 has the T shape, moreover, the aspect ratio of the contact is more improved than hitherto, so that the degree of allowance for a process for filling and forming the wiring layer MH1 can be enhanced.

In the first embodiment, the formation of the contact hole CH2 having the great width takes place before the formation of the contact hole CH1 having the narrow width. However, the formation of the contact hole CH2 may take place after the formation of the contact hole CH1.

### Second embodiment

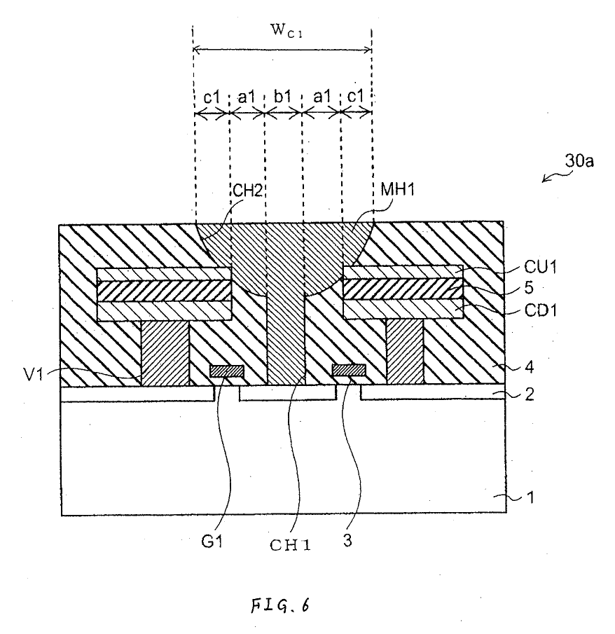

Description will now be given with reference to the drawings with regard to a semiconductor memory and a method of manufacturing the same according to a second embodiment of the present invention. FIG. 6 is a cross-sectional view showing a memory cell unit of ferroelectric memory. In the second embodiment, chain FeRAM to act as the ferroelectric memory is employed and is constructed to have a reduced distance between ferroelectric film capacitors, have a contact hole of an altered shape, and have a simplified connection between the ferroelectric film capacitor and a memory cell transistor, as compared to the first embodiment.

As shown in FIG. 6, ferroelectric memory (or chain FeRAM) 30a includes the source-drain region 2 selectively disposed on top of the semiconductor substrate 1, and the source-drain region 2 is of an opposite conduction type to that of the semiconductor substrate 1 of the memory cell transistor. The gate electrode G1 is selectively disposed above the region between the source-drain regions 2 with the gate insulating film 3 in between. The insulating film 4 is disposed as coating the source-drain region 2 and the gate electrode G1.

The vias (or plug electrodes) V1 are disposed so that the right and left source-drain regions 2 are partially exposed therethrough. The ferroelectric capacitor, which is formed of the capacitor lower electrode CD1, the ferroelectric film 5 and the capacitor upper electrode CU1 and is larger than the via (or plug electrode) V1, is formed as stacked on top of the via (or plug electrode) V1.

The contact hole CH1 is disposed in the insulating film 4 formed between the two gate electrodes G1 so that the central source-drain region 2 is exposed therethrough. The width of the contact hole CH1 is of a dimension b1. The contact hole CH2, which the capacitor upper electrode CU1 is partially exposed through and which has the greater width W_{c1} than that of the contact hole CH1 and has a curve shape, is disposed above the contact hole CH1. The contact hole area above the exposed central source-drain region 2 is filled with the wiring layer MH1 with the same height as that of the insulating film 4.

The wiring layer MH1 has the function of acting as the wiring to provide the electrical connection between the source-drain region 2 and the ferroelectric capacitor and the function of acting as the via (or via electrode) of the source-drain region 2.

At this point, the width of the contact hole CH1 is of the dimension b1, and the gap between the contact hole CH1 and the capacitor upper electrode CU1 is of a dimension a1. The capacitor upper electrode CU1 and the wiring layer MH1 are formed as overlapping by a dimension c1. The gap between the ferroelectric capacitors is set to (2×a1)+b1, which is narrower than that of the first embodiment, as expressed by Equation (1).

(2×a1)+b1<(2×a)+b (1)

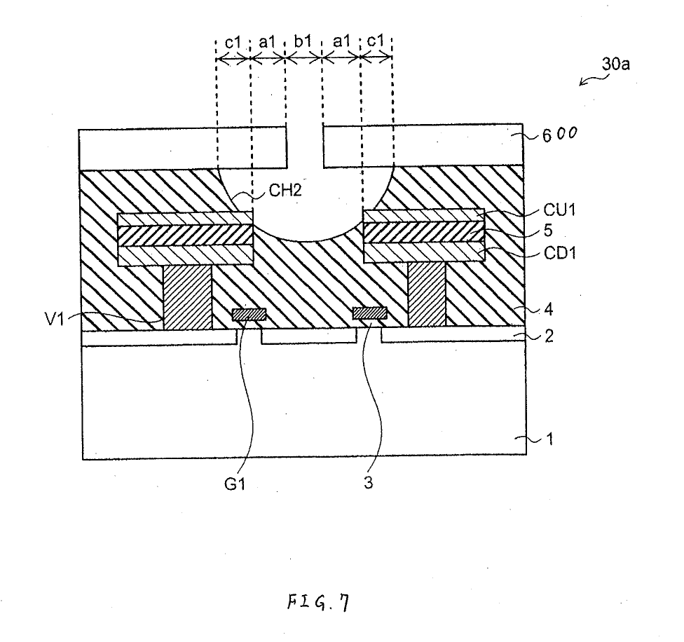

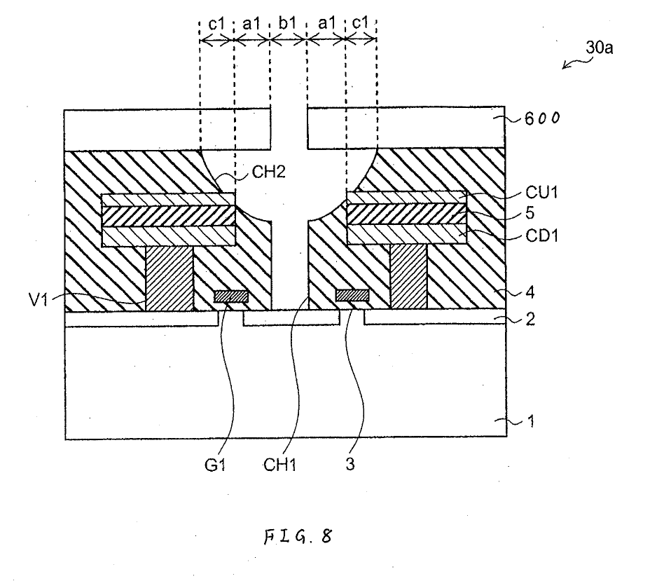

Description will now be given with reference to FIGS. 7 and 8 with regard to a method of manufacturing the ferroelectric memory. FIGS. 7 and 8 are cross-sectional views showing steps in a manufacturing process for the ferroelectric memory. Since the deposition of the insulating film 4 and the preceding process steps are the same as those of the first embodiment, description thereof will hereinafter be omitted.

As shown in FIG. 7, the resist film 600 for use in the formation of the upper contact hole CH2 is formed by use of well-known lithography technique. At this point, the resist film 600 is such that the width of the opening therein is of the dimension b1 and the gap between the ferroelectric capacitor region and the opening is of the dimension a1.

Then, the insulating film 4 is etched in substantially a curve shape partway through the ferroelectric capacitor region by use of, for example, isotropic dry etching method (also called “CDE (chemical dry etching)”) with the resist film 600 acting as a mask. At this point, with the isotropic dry etching method, the capacitor upper electrode CU1 undergoes little etching because the etching rate of the insulating film 4 is very great relative to that of the capacitor upper electrode CU1 (that is, the selective etching ratio of the etching rate of the insulating film 4 to the etching rate of the capacitor upper electrode CU1 is large).

As shown in FIG. 8, then, the lower contact hole CH1 is formed by perpendicularly etching the insulating film 4 to the source-drain region 2 by use of, for example, RIE method with the resist film 600 acting as a mask. Since the removal of the resist film 600 and the subsequent process steps are the same as those of the first embodiment, description thereof will be omitted.

According to the semiconductor memory and the method of manufacturing the same according to the second embodiment of the present invention, as described above, the vias (or plug electrodes) V1 are disposed so that the right and left source-drain regions 2 of the memory cell transistors are partially exposed therethrough. The ferroelectric capacitor formed of the capacitor lower electrode CD1, the ferroelectric film 5, and the capacitor upper electrode CU1 is formed as stacked on top of the via (or plug electrode) V1. The contact hole CH1 is disposed in the insulating film 4 formed between the two gate electrodes G1 so that the central source-drain region 2 is exposed therethrough. The contact hole CH2, which the capacitor upper electrode CU1 is partially exposed through and which is larger than the contact hole CH1 and is of substantially the curve shape, is disposed above the contact hole CH1. The same resist film is used to form the contact hole CH1 and the contact hole CH2. The contact area above the exposed central source-drain region 2 is filled with the wiring layer MH1 with the same height as that of the insulating film 4. The wiring layer MH1 has the function of acting as the wiring to provide the electrical connection between the source-drain region 2 and the ferroelectric capacitor and the function of acting as the via (or via electrode) of the source-drain region 2.

Thereby, the second embodiment can reduce the number of processes for resist formation for contact hole formation to one, thus reduce the time required for a contact forming process, and thus make the manufacturing process simpler as compared to the first embodiment. Because of using a single mask for the contact hole formation, moreover, the second embodiment can make the memory cell transistor finer and make a chip of the ferroelectric memory smaller as compared to the first embodiment.

### Third embodiment

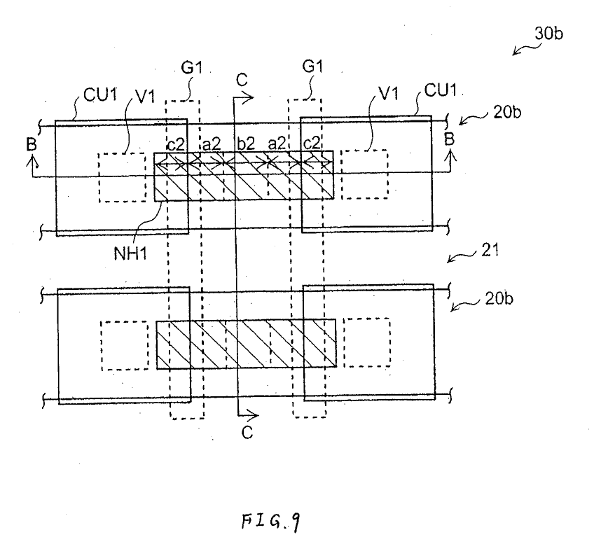

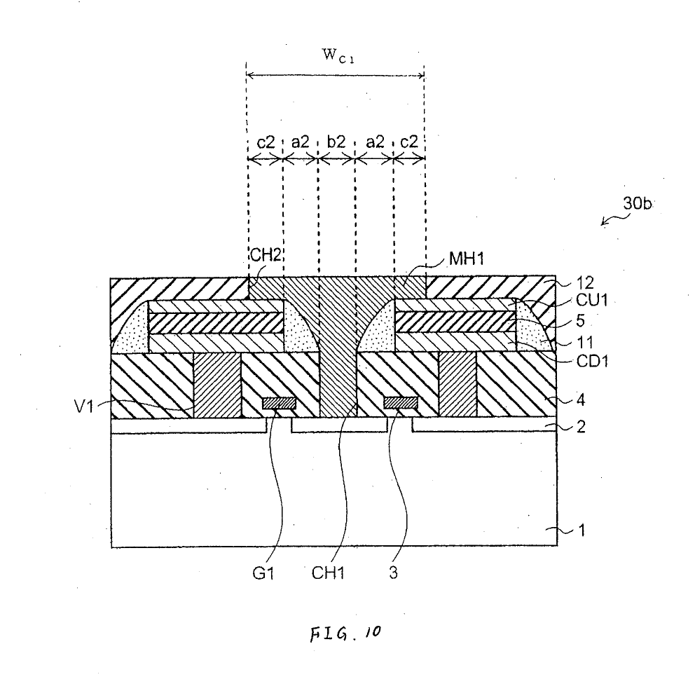

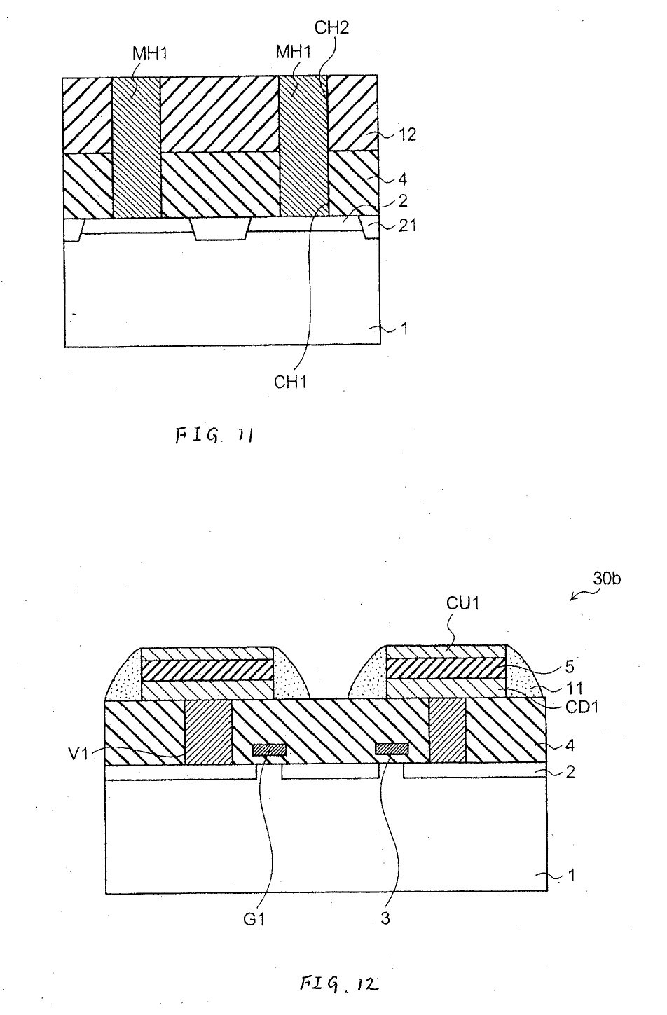

Description will now be given with reference to the drawings with regard to a semiconductor memory and a method of manufacturing the same according to a third embodiment of the present invention. FIG. 9 is a plan view showing a memory cell unit of ferroelectric memory, FIG. 10 is a cross-sectional view taken along the line B-B of FIG. 9, showing the memory cell unit of the ferroelectric memory, and FIG. 11 is a cross-sectional view taken along the line C-C of FIG. 9, showing the memory cell unit of the ferroelectric memory. In the third embodiment, chain FeRAM to act as the ferroelectric memory is employed and is constructed to have a reduced distance between ferroelectric film capacitors and have a simplified connection between the ferroelectric film capacitor and a memory cell transistor, as compared to the second embodiment.

As shown in FIG. 9, ferroelectric memory (or chain FeRAM) 30b is provided with plural memory cell transistor units 20b and the STI 21 that acts as the device isolation region.

The memory cell transistor unit 20b includes the plural memory cell transistors formed as arranged from side to side of FIG. 9, and is provided with the gate electrode G1, the contact hole CH1, the via (or plug electrode) V1, the capacitor upper electrode CU1, and the wiring layer MH1. The memory cell transistor unit 20b is isolated on its periphery by the STI 21.

The plural gate electrodes G1 are formed in a parallel arrangement, as being spaced at predetermined intervals across the plural memory cell transistor units 20b from top to bottom of FIG. 9. The contact hole CH1 is formed as disposed between the gate electrodes G1 and G1 and also within the memory cell transistor unit 20b. The via (or plug electrode) V1 is formed as disposed immediately underneath the ferroelectric capacitor. The wiring layer MH1 is formed as extending over the contact hole CH1 and to the capacitor upper electrode CU1, and is formed in a smaller longitudinal dimension than that of the first embodiment, as viewed in FIG. 9.

The width of the contact hole CH1 is of a dimension b2, and the gap between the contact hole CH1 and the capacitor upper electrode CU1 is of a dimension a2. The capacitor upper electrode CU1 and the wiring layer MH1 are formed as overlapping by a dimension c2, and they are in contact with each other in an area of the dimension c2.

At this point, the gap between the ferroelectric capacitors is set to (2×a2)+b2, which is narrower than those of the first and second embodiments, as expressed by Equation (2).

(2×a2)+b2<(2×a1)+b1<(2×a)+b (2)

As shown in FIG. 10, plural source-drain regions 2 of an opposite conduction type to that of the semiconductor substrate 1 of the memory cell transistor are selectively disposed on top of the semiconductor substrate 1 along the major axis of the memory cell transistor unit 20b of the ferroelectric memory (or chain FeRAM) 30b (that is, from side to side of FIG. 9). The gate electrode G1 is selectively disposed above the region between the source-drain regions 2 with the gate insulating film 3 in between. The insulating film 4 is disposed as coating the source-drain region 2 and the gate electrode G1.

The vias (or plug electrodes) V1 are disposed so that the right and left source-drain regions 2 are partially exposed therethrough. The ferroelectric capacitor, which is formed of the capacitor lower electrode CD1, the ferroelectric film 5 and the capacitor upper electrode CU1 and is larger than the via (or plug electrode) V1, is formed as stacked on top of the via (or plug electrode) V1.

Sidewall films 11 having substantially a triangular shape are formed on the sides of the ferroelectric capacitor. An insulating film 12 to act as an interlayer dielectric is disposed on the ferroelectric capacitor, the sidewall film 11 and the insulating film 4.

The contact hole CH1 is disposed in the insulating film 4 formed between the two gate electrodes G1 so that the central source-drain region 2 is exposed therethrough. The contact hole CH2, which the capacitor upper electrode CU1 is partially exposed through and which has the greater width W_{c1} than that of the contact hole CH1, is disposed above the contact hole CH1. The contact hole formed of the contact hole CH1 and the contact hole CH2 has substantially a T shape. The contact hole area above the exposed central source-drain region 2 is filled with the wiring layer MH1 with the same height as that of the insulating film 4.

The wiring layer MH1 has the function of acting as the wiring to provide the electrical connection between the source-drain region 2 and the ferroelectric capacitor and the function of acting as the via (or via electrode) of the source-drain region 2.

As shown in FIG. 11, the source-drain regions 2 of the opposite conduction type to that of the semiconductor substrate 1 of the memory cell transistor are selectively disposed, as isolated by the STI 21, on top of the semiconductor substrate 1 along the minor axis of the memory cell transistor unit 20b of the ferroelectric memory (or chain FeRAM) 30b (that is, from top to bottom of FIG. 9).

The contact hole CH1 is disposed in the insulating film 4 formed on the source-drain region 2 so that the central source-drain region 2 is exposed therethrough. The contact hole CH2 is disposed in the insulating film 12 formed on the insulating film 4, as having the same width as that of the contact hole CH1 and being located at the same position as that of the contact hole CH1. The contact area above the exposed central source-drain region 2 is filled with the wiring layer MH1 with the same height as that of the insulating film 4.

At this point, the width of the contact hole CH1 is the same as that of the contact hole CH2, but the width of the contact hole CH2 may be greater than that of the contact hole CH1.

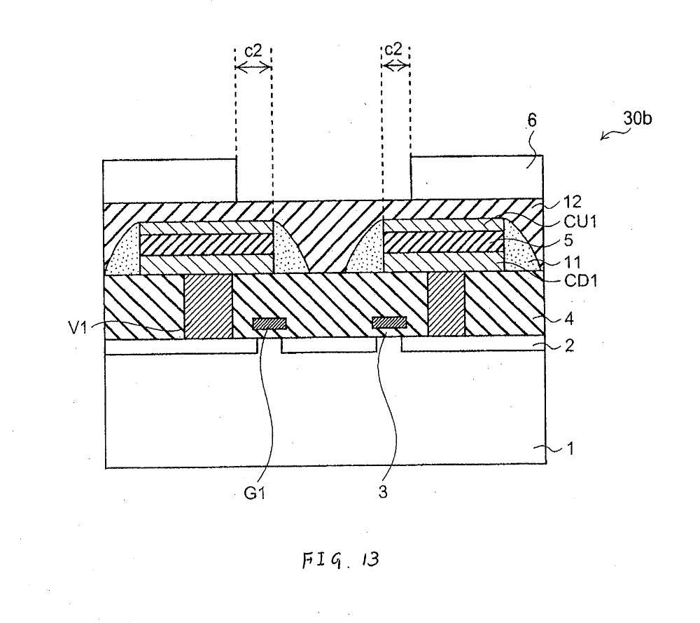

Description will now be given with reference to FIGS. 12 to 14 with regard to a method of manufacturing the ferroelectric memory. FIGS. 12 to 14 are cross-sectional views showing steps in a manufacturing process for the ferroelectric memory. Since the formation of the ferroelectric capacitor and the preceding process steps are the same as those of the first embodiment, description thereof will hereinafter be omitted.

As shown in FIG. 12, the sidewall films 11 are selectively formed on the sides of the ferroelectric capacitor. Specifically, an insulating film to form the sidewall film 11 is formed on the insulating film 4 and the ferroelectric capacitor, and the insulating film on the ferroelectric capacitor and between the ferroelectric capacitors, having a relatively small film thickness, is etched away by use of, for example, RIE method to thereby yield the sidewall film 11.

At this point, desirably, Al₂O₃ (aluminum oxide) is used for the sidewall film 11, because, with the RIE method, the etching rate of the sidewall film 11 made of Al₂O₃ (aluminum oxide) is greater than that of the capacitor upper electrode CU1 and the insulating film 4 made of a silicon oxide (SiO₂) base film. HfO (hafnium oxide), AlHfO, TiO (titanium oxide), ZrO (zirconium oxide), PZT, or the like may be used in place of Al₂O₃ (aluminum oxide).

Although the sidewall films 11, as employed herein, remain on the sides of the capacitor upper electrode CU1, the sidewall films 11 may remain at least on the sides of the capacitor lower electrode CD1 to such an extent that the gate electrode G1 is not exposed when the contact hole CH1 is formed.

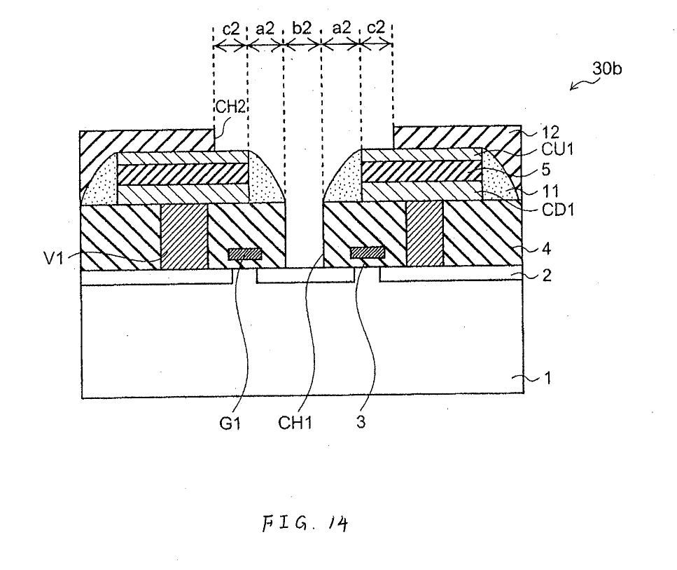

As shown in FIG. 13, then, the insulating film 12 is deposited on the capacitor upper electrode CU1, the sidewall films 11 and the insulating film 4. Desirably, an insulating film made of a silicon oxide (SiO₂) base film is used for the insulating film 12, as in the case of the insulating film 4.

Then, the resist film 6 for use in the formation of the upper contact hole CH2 and the lower contact hole CH1 is formed by use of well-known lithography technique. At this point, the resist film 6 is formed as remaining by the dimension c2 inwardly of the ferroelectric capacitor region from the edge of the ferroelectric capacitor region.

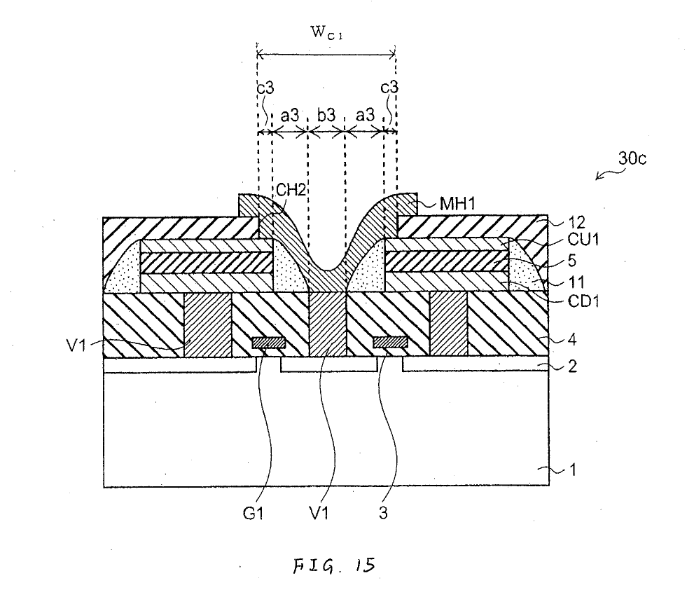

As shown in FIG. 14, then, the upper contact hole CH2 and the lower contact hole CH1 are formed by perpendicularly etching the insulating film 12 and the insulating film 4 to the source-drain region 2 by use of, for example, RIE method with the resist film 6 acting as a mask.

Incidentally, with the RIE method, the capacitor upper electrode CU1 and the sidewall film 11 undergo little etching, because etching takes place under the condition that the etching rate of the insulating film 12 and the insulating film 4 is very great relative to that of the capacitor upper electrode CU1 and the sidewall film 11 (that is, the selective etching ratio of the etching rate of the insulating film 12 and the insulating film 4 to the etching rate of the capacitor upper electrode CU1 and the sidewall film 11 is large), for example because an etching gas that permits a large selective etching ratio is used for the etching. Since the removal of the resist film 6 and the subsequent process steps are the same as those of the first embodiment, description thereof will be omitted.

According to the semiconductor memory and the method of manufacturing the same according to the third embodiment of the present invention, as described above, the vias (or plug electrodes) V1 are disposed so that the right and left source-drain regions 2 of the memory cell transistors are partially exposed therethrough. The ferroelectric capacitor formed of the capacitor lower electrode CD1, the ferroelectric film 5 and the capacitor upper electrode CU1 is formed as stacked on top of the via (or plug electrode) V1. The contact hole CH1 is disposed in the insulating film 4 formed between the two gate electrodes G1 so that the central source-drain region 2 is exposed therethrough. The contact hole CH2, which the capacitor upper electrode CU1 is partially exposed through and which is larger than the contact hole CH1, is disposed above the contact hole CH1. The sidewall films 11 are disposed on the sides of the ferroelectric capacitor, and the same resist film is used to form the contact hole CH1 and the contact hole CH2. The contact area above the exposed central source-drain region 2 is filled with the wiring layer MH1 with the same height as that of the insulating film 4. The wiring layer MH1 has the function of acting as the wiring to provide the electrical connection between the source-drain region 2 and the ferroelectric capacitor and the function of acting as the via (or via electrode) of the source-drain region 2.

Thereby, the third embodiment can reduce the number of processes for the resist formation for the contact hole formation to one, thus reduce the time required for the contact forming process, and thus make the manufacturing process simpler as compared to the first embodiment. Moreover, the width of the contact hole CH1 is the gap between the ferroelectric capacitors ((2×a2)+b2) minus double the width (a2) of the bottom of the sidewall film 11 ((a2)×2), and it is not required that the width of the contact hole CH1 be set allowing for a component such as mask alignment accuracy, and hence the gap between the ferroelectric capacitors and the width of the contact hole CH1 can become narrower as compared to the first and second embodiments. The contact hole can be of a gently sloped configuration because of the presence of the sidewall films 11 having substantially the triangular shape, and hence the degree of allowance for the process for filling and forming the wiring layer MH1 can be enhanced. Therefore, the third embodiment can make the memory cell transistor finer and make the chip of the ferroelectric memory smaller as compared to the second embodiment.

### Fourth embodiment

Description will now be given with reference to the drawing with regard to a semiconductor memory according to a fourth embodiment of the present invention. FIG. 15 is a cross-sectional view showing a memory cell unit of ferroelectric memory. In the fourth embodiment, chain FeRAM to act as the ferroelectric memory is employed and is constructed to have a reduced distance between ferroelectric film capacitors and have a simplified connection between the ferroelectric film capacitor and a memory cell transistor without the use of the damascene method, as compared to the second embodiment.

As shown in FIG. 15, ferroelectric memory (or chain FeRAM) 30c includes the source-drain region 2 selectively disposed on top of the semiconductor substrate 1, and the source-drain region 2 is of an opposite conduction type to that of the semiconductor substrate 1 of the memory cell transistor. The gate electrode G1 is selectively disposed above the region between the source-drain regions 2 with the gate insulating film 3 in between. The insulating film 4 is disposed as coating the source-drain region 2 and the gate electrode G1.

The vias (or plug electrodes) V1 are disposed so that the source-drain regions 2 are partially exposed therethrough. The ferroelectric capacitor, which is formed of the capacitor lower electrode CD1, the ferroelectric film 5, and the capacitor upper electrode CU1 and is larger than the via (or plug electrode) V1, is formed as stacked on top of each of the right and left vias (or plug electrodes) V1.

The sidewall films 11 having substantially the triangular shape are disposed on the sides of the ferroelectric capacitor, and the insulating film 12 is formed on the ferroelectric capacitor, the sidewall film 11 and the insulating film 4. The contact hole GH2 having substantially a V shape is disposed in the insulating film 12 above a region between the ferroelectric capacitors. The wiring layer MH1 is formed in the contact hole CH2. The wiring layer MH1 is disposed on the central via (or plug electrode) V1, as being in contact with the via (or plug electrode) V1.

The wiring layer MH1 has the function of acting as the wiring to provide the electrical connection between the source-drain region 2 and the ferroelectric capacitor and the function of acting as the via (or via electrode) of the source-drain region 2.

The width of the bottom of the contact hole CH2 is of a dimension b3, the width of the top thereof is W_{c1} (W_{c1}>>b3), and the gap between the bottom of the contact hole CH2 and the capacitor upper electrode CU1 is of a dimension a3. The capacitor upper electrode CU1 and the wiring layer MH1 are formed as overlapping by a dimension c3, and they are in contact with each other in an area of the dimension c3.

The gap between the ferroelectric capacitors is set to (2×a3)+b3, which is narrower than those of the first and second embodiments, as expressed by Equation (3).

(2×a3)+b3<(2×a1)+b1<(2×a)+b (3)

At this point, the ferroelectric capacitor formed of the capacitor lower electrode CD1, the ferroelectric film 5 and the capacitor upper electrode CU1 has a smaller thickness (or a lower aspect ratio) as compared to the third embodiment. Thus, sputtering method rather than the damascene method can be used to form the wiring layer MH1. Although the damascene method using CVD method or the like involves emission of hydrogen that can possibly cause deterioration in characteristics of the ferroelectric capacitor, the sputtering method can prevent the deterioration in the characteristics of the ferroelectric capacitor because of involving no hydrogen emission.

According to the semiconductor memory and the method of manufacturing the same according to the fourth embodiment of the present invention, as described above, the vias (or plug electrodes) V1 are disposed so that the source-drain regions 2 of the memory cell transistors are partially exposed therethrough. The ferroelectric capacitor formed of the capacitor lower electrode CD1, the ferroelectric film 5 and the capacitor upper electrode CU1 is formed as stacked on top of each of the right and left vias (or plug electrodes) V1 shown in FIG. 15. The via (or plug electrode) V1 is disposed in the insulating film 4 formed between the two gate electrodes G1 so that the central source-drain region 2 is exposed therethrough. The sidewall films 11 are disposed on the sides of the ferroelectric capacitor, a region between the bottoms of the sidewall films 11 of the ferroelectric capacitors forms a contact (or the bottom of the contact hole CH2) to provide a connection to the via (or plug electrode) V1, and the width of the top of the contact hole CH2 is greater than the gap between the ferroelectric capacitors. The wiring layer MH1 is formed in the contact area above the exposed central via (or plug electrode) V1 by use of the sputtering method. The wiring layer MH1 has the function of acting as the wiring to provide the electrical connection between the source-drain region 2 and the ferroelectric capacitor and the function of acting as the via (or via electrode) of the source-drain region 2.

Thereby, besides achieving the advantageous effects of the first to third embodiments, the fourth embodiment can prevent the deterioration in the ferroelectric capacitor because of using the sputtering method, rather than the damascene method using CVD method or the like, to form the wiring layer MH1.

As described above, present embodiments can provide a semiconductor memory and a method of manufacturing the same, which are capable of simplifying a cell-by-cell connection between an upper electrode of a ferroelectric capacitor and a memory cell transistor.

It is to be understood that the present invention is not limited to the above embodiments, and various changes and modifications may be made in the invention without departing from the spirit and scope of the invention.

For example, the present invention may be applied to chain PRAM (phase change random access memory) or the like, although in the embodiments the present invention is applied to the chain FeRAM.

What is claimed is:

1. A semiconductor memory, comprising:
a first memory cell transistor disposed on a semiconductor substrate;
a second memory cell transistor disposed on the semiconductor substrate and having a first source-drain region in common with the first memory cell transistor;
a first ferroelectric capacitor disposed with a via in between above a second source-drain region of the first memory cell transistor;
a second ferroelectric capacitor disposed with a via in between above a second source-drain region of the second memory cell transistor;
an interlayer dielectric disposed on the semiconductor substrate, as coating the memory cell transistors and the ferroelectric capacitors, the interlayer dielectric having a contact hole through which the first source-drain region is partially exposed at the bottom and upper electrodes of the first and second ferroelectric capacitors are partially exposed at the top; and
a wiring layer filled into the contact hole, which connects the first source-drain region, the upper electrode of the first ferroelectric capacitor, and the second ferroelectric capacitor.

2. The semiconductor memory according to claim 1, wherein the contact hole is formed in such a manner that a top opening width is greater than a bottom opening width.

3. The semiconductor memory according to claim 2,
wherein sidewall films are disposed on the sides of the first and second ferroelectric capacitors, and
the sides of the sidewall films are exposed into the contact hole and are in contact with the wiring layer.

4. A semiconductor memory, comprising:
a first memory cell transistor disposed on a semiconductor substrate;
a second memory cell transistor disposed on the semiconductor substrate and having a first source-drain region in common with the first memory cell transistor;
a first ferroelectric capacitor formed of a capacitor lower electrode, a ferroelectric film and a capacitor upper electrode, disposed with a via in between above a second source-drain region of the first memory cell transistor;
a second ferroelectric capacitor formed of the capacitor lower electrode, the ferroelectric film and the capacitor upper electrode, disposed with a via in between above a second source-drain region of the second memory cell transistor;
a sidewall film disposed on each of the sides of the first and second ferroelectric capacitors;
an interlayer dielectric disposed on the semiconductor substrate, as coating the memory cell transistors, the ferroelectric capacitors and the sidewall films, the interlayer dielectric having a contact hole through which the first source-drain region is partially exposed at the bottom and the upper edges of the upper electrodes of the first and second ferroelectric capacitors and the sides of the sidewall films are exposed at the top; and
a wiring layer filled into the contact hole, which connects the first source-drain region, the upper electrode of the first ferroelectric capacitor, and the second ferroelectric capacitor.

5. A semiconductor memory, comprising:
a first memory cell transistor disposed on a semiconductor substrate;
a second memory cell transistor disposed on the semiconductor substrate and having a first source-drain region in common with the first memory cell transistor;
a first ferroelectric capacitor formed of a capacitor lower electrode, a ferroelectric film and a capacitor upper electrode, disposed with a via in between above a second source-drain region of the first memory cell transistor;
a second ferroelectric capacitor formed of the capacitor lower electrode, the ferroelectric film and the capacitor upper electrode, disposed with a via in between above a second source-drain region of the second memory cell transistor;
a sidewall film disposed on each of the sides of the first and second ferroelectric capacitors; and
a wiring layer disposed, in contact with the sides of the sidewall films, on the first source-drain region of the first and second memory cell transistors, which connects the via, the capacitor upper electrode of the first ferroelectric capacitor, and the capacitor upper electrode of the second ferroelectric capacitor.

6. A method of manufacturing a semiconductor memory, comprising:
forming a contact opening in a first interlayer dielectric formed on a source-drain region of a memory cell transistor, and selectively forming sidewall films on the sides of first and second ferroelectric capacitors each formed above the source-drain region of the memory cell transistor with a via filled into the contact opening in between;
forming a first contact by exposing the first ferroelectric capacitor, the second ferroelectric capacitor and the sidewall films by etching a second interlayer dielectric formed on the sidewall films, the first ferroelectric capacitor and the second ferroelectric capacitor by use of RIE method with a resist film acting as a mask;
forming a second contact by exposing the source-drain region of the memory cell transistor by etching the first interlayer dielectric by use of the RIE method with the sidewall films acting as a mask; and
filling a wiring layer into the first and second contacts.

7. A method of manufacturing a semiconductor memory, comprising:
forming a contact opening in a first interlayer dielectric formed on a source-drain region of a memory cell transistor, and forming first and second ferroelectric capacitors above the source-drain region of the memory cell transistor with a via filled into the contact opening in between;
forming a first contact by etching a second interlayer dielectric formed on the first and second ferroelectric capacitors by use of RIE method with a first resist film acting as a mask until the first and second ferroelectric capacitors are partially exposed;
forming a second contact having a narrower width than that of the first contact, by exposing the source-drain region of the memory cell transistor by etching the first and second interlayer dielectrics by use of the RIE method with a second resist film acting as a mask, the second resist film having an opening formed between the first and second ferroelectric capacitors; and
filling a wiring layer into the first and second contacts.

8. The method of manufacturing a semiconductor memory according to claim 7, wherein the wiring layer is formed by means of the damascene method using CVD method.

9. The method of manufacturing a semiconductor memory according to claim 7, wherein the wiring layer is formed by means of the damascene method using electroplating method.

10. A method of manufacturing a semiconductor memory, comprising:
forming a contact opening in a first interlayer dielectric formed on a source-drain region of a memory cell transistor, and forming first and second ferroelectric capacitors above the source-drain region of the memory cell transistor with a via filled into the contact opening in between;
forming a first contact by etching a second interlayer dielectric formed on the first and second ferroelectric capacitors by use of isotropic dry etching method with a resist film acting as a mask until the first and second ferroelectric capacitors are partially exposed;
forming a second contact having a narrower width than that of the first contact, by exposing the source-drain region of the memory cell transistor by etching the first and second interlayer dielectrics by use of RIE method with the resist film acting as a mask; and
filling a wiring layer into the first and second contacts.

11. The method of manufacturing a semiconductor memory according to claim 10, wherein the wiring layer is formed by means of the damascene method using CVD method.

12. The method of manufacturing a semiconductor memory according to claim 10, wherein the wiring layer is formed by means of the damascene method using electroplating method.
